(19) United States
(12) Patent Application Publication
(10) Pub. No.: US 2009/0184382 A1
(43) Pub. Date: Jul. 23, 2009

(54) METHOD TO REDUCE DISLOCATION DENSITY IN SILICON

(76) Inventors: Katherine Hartman, Schenectady, NY (US); James Serdy, Boston, MA (US); Tonio Buonassisi, Cambridge, MA (US)

Correspondence Address: GAUTHIER & CONNORS, LLP, 225 FRANKLIN STREET, SUITE 2300, BOSTON, MA, 02110, US

(21) Appl. No.: 12/358,755

(22) Filed: Jan. 23, 2009

Related U.S. Application Data
(60) Provisional application No. 61/022,938, filed on Jan. 23, 2008.

(51) Int. Cl. H01L 31/036; H01L 21/34; H01L 31/18

(52) U.S. Cl. 257/431; 438/795; 438/57

(57) ABSTRACT

A crystalline material structure is provided. The crystalline material structure includes a semiconductor structure being annealed at temperatures above the brittle-to-ductile transition temperature of the semiconductor structure, and cooled in an approximately linear time-temperature profile down to approximately its respective transition temperature T₀.

### PRIORITY INFORMATION

This application claims priority from provisional application Ser. No. 61/022,938 filed Jan. 23, 2008, which is incorporated herein by reference in its entirety.

### BACKGROUND OF THE INVENTION

The invention is related to the field of semiconductor fabrication and processing, and in particular to a technique to reduce dislocations in silicon wafers during growth of semiconductor materials, or during the processing of existing semiconductor materials.

Solar cell production is coming of age. The production of solar cells and modules (not counting installation, balance of systems, and downstream integration) is now exceeding a $25B business worldwide, with cumulative market capitalization over an order of magnitude larger.

Over 50% of solar cells produced today are manufactured from multicrystalline (mc) silicon wafers. The electrical properties of the solar cell devices that are manufactured on mc-Si wafer substrates are extremely sensitive to the density of defects present in these materials. Defects inside the solar cell wafers, commonly referred to as “bulk defects” (e.g., impurities and structural defects), are particularly deleterious for solar cell efficiencies. The most damaging bulk defects are those that are most uniformly distributed, such as one-dimensional structural defects known as dislocations.

### SUMMARY OF THE INVENTION

According to one aspect of the invention, there is provided a method of reducing dislocation density in a crystalline material structure is provided. The method includes annealing the crystalline material structure at temperatures above the brittle-to-ductile transition temperature of the crystalline material. Also, the method includes cooling the crystalline material structure in an approximately linear time-temperature profile down to approximately a transition temperature T₀.

According to another aspect of the invention, there is provided a crystalline material structure. The crystalline material structure includes a semiconductor structure being annealed at temperatures above the brittle-to-ductile transition temperature of the semiconductor structure, and cooled in an approximately linear time-temperature profile down to approximately its respective transition temperature T₀.

### BRIEF DESCRIPTION OF THE DRAWINGS

FIG. 1 is a flowchart illustrating one embodiment of the steps used in performing the inventive technique; and

FIGS. 2A-2B are dislocation density images illustrating the removal of dislocation in a multicrystalline Si structure.

### DETAILED DESCRIPTION OF THE INVENTION

The invention provides a technique to reduce dislocation densities in crystalline materials. A crystalline material is one that has a regularly repeating pattern of atoms or molecules (commonly defined in solid state physics as the same grouping of atoms or molecules (the “basis”) around each lattice point). One such example of a crystalline material is crystalline silicon, a solid material with a diamond cubic structure. The physical size and shape of said crystalline materials can in principle be any form, for instance, a wafer, a ribbon, or a block. This invention incorporates three elements to significantly reduce the dislocation density:

The first element is using very-high-temperature annealing to eliminate dislocations. One temperature meriting definition is the “brittle-to-ductile transition temperature”, the temperature at which brittle crystalline solids become ductile, i.e., the temperature above which dislocations become mobile within the material. The brittle-to-ductile transition temperature is typically around 0.8 times the melting temperature (in kelvin) of most crystalline solids. Once dislocations are mobile within the material, several pathways for dislocation annihilation are possible, e.g., pairwise annihilation or out-diffusion. Such is the case for steels and other metals. In silicon, three temperatures to date are attempted: 1366° C., 1233° C., and 1100° C. Samples annealed at 1366° C. exhibited a noticeable decrease in dislocation density, samples annealed at 1233° C. exhibited an intermediate decrease in dislocation density, while samples annealed at 1100° C. did not exhibit a large dislocation density reduction, even at extended annealing times. One can suspect there can be a shorter time and lower temperature at which dislocation densities can be appreciably reduced. As this is a kinetic process, there exists an inherent tradeoff between time and temperature, e.g., lower temperature anneals appear to require longer annealing times to achieve the same reduction in dislocation density. Because of this trade-off, it should be possible to achieve a substantial dislocation density reduction within a reasonable amount of time, by annealing within a well-specified and limited range of annealing times and temperatures.

The second element is the formation of a diffusion barrier to slow the entry of harmful impurities. A diffusion barrier is formed on the silicon wafer or ingot surface before annealing, and is generally removed after annealing. Note a diffusion barrier is optional when using a block-like structure, as the outer material itself may act as an impurity diffusion barrier for slowly-diffusing impurities. The diffusion barrier is formed of an inert substance that is appreciably thick, to slow the indiffusion of deleterious metallic impurities (e.g., Ti and Al), and can be easily removed after annealing. Silicon nitride, which etches away in HF, is one such candidate material.

The third element is controlled cool to room temperature. It is currently believed that the preferred time-temperature profile during cooling to room temperature should be kept as linear as possible, and the temperature throughout the material be kept as uniform as possible, to avoid thermal stresses that may cause new dislocations to form. Satisfying these two criteria sets an estimate for the maximum cooling rate. It is currently believed to be important to maintain a linear time-temperature profile and uniform temperature throughout the material down to the T₀ transition temperature, defined herein as the temperature at which thermally activated dislocation motion is severely inhibited. For many crystalline materials, T₀ is typically given as the brittle-to-ductile transition temperature. However, for crystalline materials wherein dislocation kink formation energies are large (hence dislocation glide is strongly preferred along certain crystallographic planes), such as crystalline silicon, T₀ (˜1100° C.) is actually several hundreds of degrees higher than the commonly-accepted brittle-to-ductile transition temperature (˜550° C.).

In one embodiment, for instance in a block-like geometry, one could envision elements one and three might be sufficient to reduce dislocation densities in multicrystalline silicon. Whereas in another embodiment, for instance a thin wafer, one could envision elements one, two, and three may be used in combination.

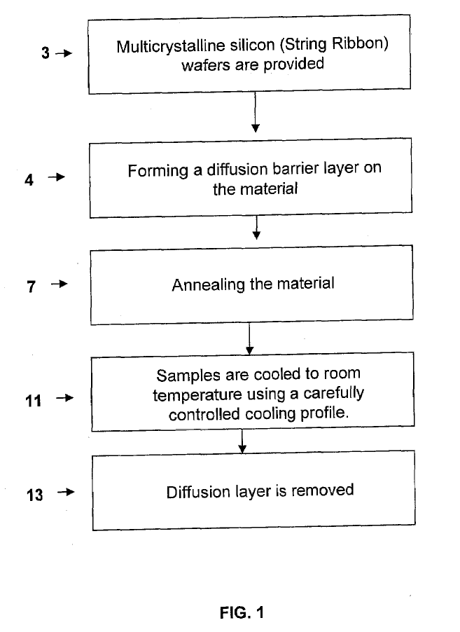

FIG. 1 is a flowchart illustrating the inventive technique of reducing dislocations in accordance with the invention. Multicrystalline silicon (String Ribbon) wafers ˜200±20 μm thick are provided, as shown in step 2. One set of samples is coated with a silicon nitride layer on both sides via plasma-enhanced chemical vapor deposition (PECVD) to form a diffusion layer, as shown in step 4. Since the grain structure (and dislocation density) of samples is fairly homogeneous along the growth direction, a wafer can be cut perpendicular to the growth direction; one piece kept as control, while the other was annealed at high temperature.

Annealing was performed in a mullite tube furnace for 6 hours. Three annealing temperatures were used: 1370 (cooling to 1366° C. over 6 hours), 1233° C., and 1100° C., as shown in step 7. Samples are slowly inserted into the furnace while the furnace was ramping up in temperature for the 1366° C. anneal, samples were inserted when the furnace was around 1200° C.; for the 1100° C. anneal, samples were inserted when the furnace was around 800° C. An S-type thermocouple was used to measure temperature. Samples are slowly cooled to room temperature over the duration of three hours, as shown in step 8, employing as linear a time-temperature profile as the power supply could enable. Samples were removed from the furnace at room temperature. The silicon nitride coating or diffusion layer is removed using hydrofluoric acid (HF), as shown in step 10. An etch to elucidate the position of structural defects (so-called “defect etch”) is performed using a slight variant of the “Sopori etch”, which is 36 parts HF; 15 parts Acetic acid (we used 20 parts); 2 parts nitric acid.

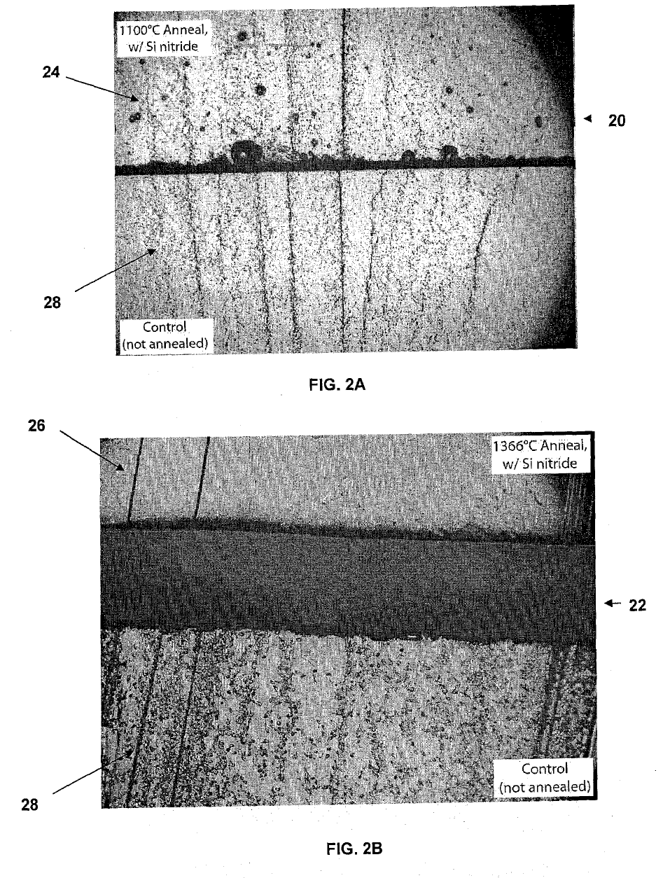

Dislocation density imaging is performed using an optical microscope. The two pieces 20, 22 of the same wafer (annealed and control) are placed face-to-face, to illustrate the change in dislocation density. Typical images for 1100° C. and 1366° C. anneals are shown in FIG. 2A-2B respectively. Dislocation etch pits appear as dark spots in this bright-field optical microscope image. The upper samples 24, 26 are the annealed; the lower 28 the control. Both annealed samples 24, 26 (1100° C. and 1366° C.) are double-sided coated with silicon nitride before annealing; this coating was etched off before defect etching and there is a clear showing of lower dislocation density in samples 26.

There is currently no established technique to reduce bulk dislocation densities in crystalline silicon materials after crystal growth. A post-solidification high-temperature anneal is already employed during crystal growth, but dislocation densities remain high nevertheless, possibly due to new dislocation formation fueled by thermal gradients within the ingot. Since it is generally easier to keep the temperature over an entire 14-gram wafer constant, as opposed to a 500,000-gram ingot, it is believed there is greater utility in performing a post-growth anneal on smaller sample sizes. In the 2 inch diameter laboratory tube furnace used in these preliminary experiments, one could expect more subtle position-dependent variances in temperature within the hot zone.

If dislocation reduction can be achieved without compromising bulk impurity concentrations, one can expect industrial solar cell efficiencies (using standard screen-printing metallization) to improve from an average of about 16% up to about 17.5% (comparable to float zone substrates). More importantly, multicrystalline silicon substrates with minority carrier lifetimes approaching those of float zone may be incorporated into higher-efficiency device architectures, such as the interdigitated back contact solar cell device architecture.

Although the present invention has been shown and described with respect to several preferred embodiments thereof, various changes, omissions and additions to the form and detail thereof, may be made therein, without departing from the spirit and scope of the invention.

What is claimed is:

1. A method of reducing dislocation density in a crystalline material structure, comprising:
annealing said crystalline material structure at temperatures above the brittle-to-ductile transition temperature of said crystalline material; and
cooling said crystalline material structure in an approximately linear time-temperature profile down to approximately its respective transition temperature T₀.

2. The method of claim 1, wherein the crystalline material structure comprises a semiconductor.

3. The method of claim 2, wherein the crystalline material structure comprises silicon.

4. The method of claim 1, wherein the crystalline material structure is a wafer, ribbon, or block.

5. The method of claim 1 further comprising a diffusion barrier formed on said material.

6. The method of claim 5, wherein said diffusion barrier comprises an inert material that slows indiffusion of impurities.

7. The method of claim 5, wherein said diffusion barrier comprises silicon nitride.

8. The method of claim 1, wherein annealing is carried out at temperatures ranging between (0.8×T_{M}) and T_{M}, where T_{M} is the melting temperature of the material.

9. The method of claim 8, wherein the crystalline material structure comprises crystalline silicon, and the temperature range is approximately 1100° C. to 1420° C.

10. The method of claim 9, wherein annealing is carried out above 1233° C.

11. The method of claim 8, wherein annealing is carried out over a period of up to 8 hours.

12. The method of claim 1, wherein cooling to the transition temperature T₀ occurs with an approximately linear time-temperature profile, over a period of up to 36 hours.

13. The method of claim 1, wherein said crystalline material structure is maintained at an approximately uniform temperature during cooling.

14. The method of claim 5, wherein said diffusion barrier is removed after annealing.

15. The method of claim 1, wherein said crystalline material structure is utilized in a solar cell.

16. A crystalline material structure comprising:
a semiconductor structure annealed at temperatures above the brittle-to-ductile transition temperature of said semiconductor structure, and cooled in an approximately linear time-temperature profile down to approximately its respective transition temperature T₀.

17. The crystalline material structure of claim 16, wherein the semiconductor structure comprises crystalline silicon.

18. The structure of claim 16, wherein the semiconductor structure is a wafer, ribbon, or block.

19. The structure of claim 16 further comprising forming a diffusion barrier on said crystalline material structure.

20. The structure of claim 19, wherein said diffusion barrier comprises an inert material that slows indiffusion of impurities.

21. The structure of claim 19, wherein said diffusion barrier comprises silicon nitride.

22. The structure of claim 16, wherein annealing is carried out at temperatures ranging between (0.8×T_{M}) and T_{M}, where T_{M} is the melting temperature of the material.

23. The structure of claim 23, wherein the semiconductor structure comprises crystalline silicon, and the temperature range is approximately 1100° C. to 1420° C.

24. The structure of claim 23, wherein annealing is carried out above 1233° C.

25. The structure of claim 22, wherein annealing is carried out over a period of up to 8 hours.

26. The structure of claim 16, wherein cooling to the transition temperature T₀ occurs with an approximately linear time-temperature profile, over a period of up to 36 hours.

27. The structure of claim 16, wherein said semiconductor structure is maintained at an approximately uniform temperature during cooling.

28. The structure of claim 19, wherein said diffusion barrier is removed after annealing.

29. The structure of claim 16, wherein said semiconductor structure is utilized in a solar cell.
